(19) United States
(12) Patent Application Publication
(10) Pub. No.: US 2018/0155126 A1
(43) Pub. Date: Jun. 7, 2018

(54) SERVICE CART

(71) Applicant: Integrated Dynamics Engineering GmbH, Raunheim (DE)

(72) Inventors: Ingo WEISKE, Frankfurt am Main (DE); Arndt EVERS, Oestrich-Winkel (DE); Han HARTGERS, Mainz (DE); Andreas BIRKNER, Jena (DE); Guido VAN LOON, Raunheim (DE)

(73) Assignee: Integrated Dynamics Engineering GmbH, Raunheim (DE)

(21) Appl. No.: 15/568,348

(22) PCT Filed: Mar. 9, 2016
(86) PCT No.: PCT/EP2016/054975

§ 371 Date: Oct. 20, 2017

(30) Foreign Application Priority Data
Apr. 22, 2015 (EP) 15164605.6

(51) Int. Cl. B65G 1/02

(52) U.S. Cl. CPC B65G 1/026; G03F 7/70

(57) ABSTRACT

The invention relates to a maintenance apparatus for a clean room or for systems in the clean room comprising a system component which can be moved horizontally and vertically. The system component is suspended on magnetic rails.

### FIELD OF THE INVENTION

The invention relates to a maintenance apparatus for use in systems in clean rooms. In particular, the invention relates to a maintenance apparatus which can be used to vertically and horizontally displace system components of a system used in the field of the semiconductor industry, in particular components of a processing system, or components of a process control system (for example a measurement sensor).

### BACKGROUND OF THE INVENTION

In the semiconductor industry, substrates are becoming larger and larger and so do the systems. The invention relates in particular to systems that may include processing systems or process control systems. Such systems often comprise system components for performing the intended application of this system in vacuum.

Such systems often comprise system components (e.g., components of a measurement sensor, components for substrate handling, of a light source, of an electron beam source, or of a multitude of other system-specific components). Other components of the system may also be mounted in the system components. For maintenance purposes, it is necessary from time to time to lift the system component and move it laterally in order to get access to the underlying devices or components or to the devices or components that are mounted in the system component itself.

For this purpose, mobile maintenance cranes are usually used. The mass to be moved can be quite high. In particular, there are system components which have a weight of more than 5 tons.

The moving of such a component using a mobile maintenance crane is time-intensive and thus leads to correspondingly cost-intensive downtimes of the system. Published patent application US 2013/0088702 A1 discloses a lifting assembly for a module of a lithography device. The lifting assembly shown in this document is integrated into the system, which results in the advantage of shorter maintenance times.

However, the mechanical components, in particular the bearings are problematic in such a system. For example, any fats or oils that are used will impair the clean room conditions. When moving loads, oil-free bearings furthermore cause unwanted abrasion, which contaminates the system or the clean room. The heavier the loads, the more significant abrasion will usually be.

A further disadvantage of the maintenance crane is that any lateral forces which can arise, for example if lateral cables or other lines for fluids or optical lines are mounted on the system component to be moved also during or after the movement, may result in the situation that the use of such a maintenance crane is not allowed for safety reasons.

### OBJECT OF THE INVENTION

Given this background, the invention is based on the object of mitigating the drawbacks of the prior art. In particular, it is an object of the invention to provide a maintenance apparatus which is useful to rapidly move heavy loads and in which the risk of particle emissions into the system or into the clean room is reduced.

### SUMMARY OF THE INVENTION

The object of the invention is already achieved by a maintenance apparatus according to claim 1. Preferred embodiments and further refinements of the invention will be apparent from the subject matter of the dependent claims.

The invention relates to a maintenance apparatus, in particular for use in systems and in clean rooms.

The system comprises a vertically and horizontally displaceable system component. As described in the introductory part, the system component may as well be part of a system, in particular of a measurement sensor, a part of a substrate handling device. The system component may further comprise system components such as components of lithography and inspection devices, or may be part of a vacuum chamber, in particular the closure of a vacuum chamber.

For this purpose, the system component may comprise passages for fluid, electrical and/or optical lines.

The system component can be displaced both in the horizontal and vertical directions. Thus, by means of the maintenance apparatus according to the invention, the system component can not only be lifted within the system but also displaced in the horizontal direction.

According to the invention, the system component comprises at least one magnetic rail, at least for the horizontal displacement. Here, magnetic rail in particular refers to a magnetic bearing which is provided in the form of a rail. The magnetic rail in particular includes solenoids which are useful to hold a carriage on a rail in a levitation condition. In the activated state, the carriage is thus lifted by magnetic forces and is spaced from the rail by at least one gap. The system component can then be displaced in the horizontal direction without contact.

Since the system component is no longer supported by roller bearings or plain bearings, it can be displaced in a horizontal direction without abrasion.

It has been found that in particular even heavy system components can be moved in the horizontal direction in contact-free manner by means of a magnetic rail.

Although the provision of such large-dimensioned magnetic rails is expensive, it has the great advantage of reducing particle emissions. Moreover, locking means could be dispensed with, in particular at the end positions of the horizontal displacement path. That is because when the magnetic rail is disconnected from power supply, the system will automatically lock itself by touchdown, so that it will then be fixed in frictional or positive-locking manner on a support. Usually, the switching off of the magnets is rather an emergency feature in the case of power failure.

Parts of the magnetic rail, in particular a beam or a carriage running on the beam, can be provided with a coating that increases the friction, for this purpose. It is also conceivable to provide the beam and the carriage with interengaging positive locking features. These may, for example, be teeth extending along a rail, into which teeth of the carriage will engage upon touching down.

Besides of dispensing with securing means for locking, it is advantageous that the carriage will be reliably locked in any position, for example even in the event of a power failure in the system during the displacement.

Alternatively or in combination, the system component can also be held in the required position by the drive.

Furthermore, mechanical locking by additional means that prevent the horizontal movement of the carriage is also conceivable. This may be implemented, for example, by positive locking features operated by an actuator, which lock the carriage of the magnetic rail on the magnetic rail.

In a preferred embodiment of the invention, the magnetic rail has a separate linear drive for the horizontal displacement. The decoupling of the lifting of the carriage of the magnetic rail by means of the magnetic rail from the horizontal displacement simplifies the implementation in terms of control engineering compared to a control of the solenoids of the magnetic rail itself. The linear drive only has to provide small forces and moreover does not need to move the system component very quickly in the horizontal direction.

To reduce abrasion, non-contact linear motors are advantageous.

However, since only small forces have to be provided, it is also conceivable to use a spindle drive for the horizontal displacement, for example. Due to the small forces this drive has to provide, the resulting abrasion will usually be less severe.

In a further embodiment of the invention, the magnetic rail has an electromagnetic lateral guide. The magnetic rail therefore has both, solenoids for lifting a carriage, and solenoids to hold the carriage in a center position spaced from the walls of a beam.

Thus, the carriage does not abut against the beam even during the displacement in the horizontal direction, which might otherwise lead to abrasion.

The electromagnetic lateral guiding is preferably provided by separate solenoids and not by the solenoids which are used to lift the carriage on the rail.

In particular, this allows to employ a simple control configuration in which the lifting of a carriage of the magnetic rail, the lateral guide and the horizontal displacement can be controlled separately and independently of each other.

In a preferred embodiment of the invention, the maintenance apparatus comprises a plurality of magnetic rails. It is in particular contemplated to provide a maintenance apparatus which comprises two magnetic rails, each one with a carriage that can be displaced on a beam along the rail or the beam.

Preferably, the system component is now connected approximately centrally, at its center of gravity, to the lateral carriages and can thus be displaced along the beam.

The movement in vertical direction, which in the context of the invention does not refer to a lifting of the system component by the activation of the magnetic rail so that it can then be moved in contact-free manner in the horizontal direction, but rather to a displacement over longer distances in the vertical direction, is preferably realized by the fact that the system component is vertically displaceable via hanger means.

In one embodiment of the invention, a non-contact drive is also used for the vertical movement, in particular a magnetic drive and/or a contact-free operating magnetic guide within the hanger means.

This again reduces particle emissions, but has the disadvantage that a locking means has to be provided in the vertical direction, by which the system component is locked in its vertical end position.

In the case of a non-contact drive it is even better to provide locking means which automatically lock the system component in the event of a power failure and thus prevent it from falling down. This can be realized, for example, by a positive locking element operated by a solenoid, which releases the beam for vertical displacement as soon as it is electrically controlled. In the event of a power failure, the positive locking element returns to its initial position and locks the beam or the hanger means by which the system component is raised.

The system component is suspended on the at least one magnetic rail, in particular on a carriage of the magnetic rail, in particular via hanger means in the form of a cable or rod. Therefore, the system component has play in the horizontal and vertical direction, so that tolerances of the involved components can be compensated for or a reduction of the transfer of vibrations from the maintenance apparatus to the often vibration-isolated system component can be achieved.

The maintenance apparatus is in particular configured for lifting a mass of more than 50 kg, preferably more than 100 kg, particularly preferably more than 1 t, most preferably more than 5 t.

Furthermore, the system component can be displaced preferably by more than 30% and/or less than 70% of its length from a central position in a horizontal direction.

In one embodiment of the invention, the carriage of the rail has an arm extending in the horizontal direction, on which the system component is mounted, in particular suspended.

In this manner, a system component which is fixed at its center of gravity can be displaced by more than half of its length, in particular completely out of the area of the system in which the magnetic rails extend.

The system component may as well be suspended in particular in the center and is thus displaceable by about half of its length in the horizontal direction. In other embodiments, the system component may as well be suspended outside of its center of gravity and/or not centrally.

The invention in particular relates to a maintenance apparatus for components of a processing system, or components of a process control system (for example a measurement sensor), or components of a lithography system, in particular to measurement devices, lithography devices, optical inspection devices, electron beam-based inspection devices, coating systems, and systems for processing semiconductor substrates. Furthermore, use thereof in systems within clean rooms of the pharmaceutical and food industry is also conceivable, in particular in production, packaging, and filling systems.

The vertical displacing movement is preferably carried out by the hanger means. In particular if the hanger means is configured as a rod, the vertical movement can be implemented there (e.g. as a threaded drive).

### BRIEF DESCRIPTION OF THE DRAWINGS

The invention will now be explained with reference to FIGS. 1 to 6 by way of schematically illustrated exemplary embodiments.

FIG. 1 shows a schematic perspective view of an exemplary embodiment of a maintenance apparatus.

FIG. 2 shows the maintenance apparatus of FIG. 1 with the system component displaced vertically upwards.

FIG. 3 shows the maintenance apparatus illustrated in FIGS. 1 and 2 with the system component displaced in the horizontal direction.

FIG. 4 shows a schematic sectional view of a magnetic rail.

FIG. 5 shows a perspective view of a magnetic rail.

FIG. 6 is a perspective view of a further embodiment of the invention, in which the system component can be moved out of the system over a longer distance.

### DETAILED DESCRIPTION

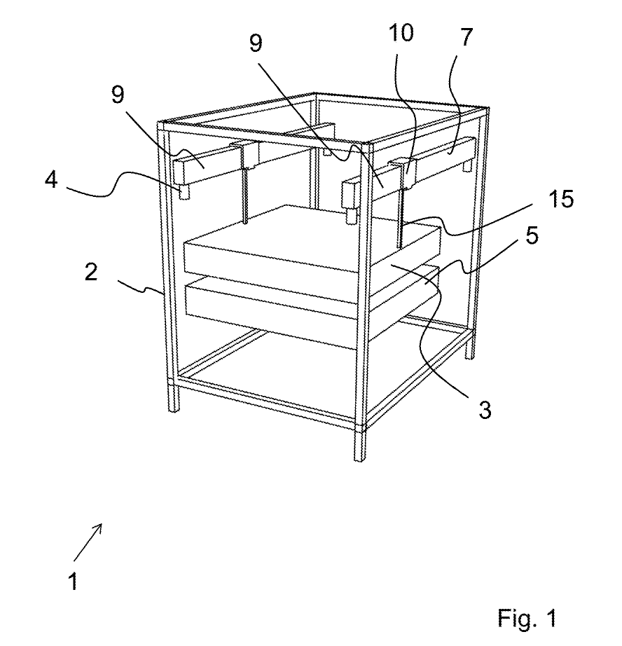

FIG. 1 shows a perspective view of a first schematic exemplary embodiment of a maintenance apparatus 1 which comprises a frame 2.

Within the frame 2, a table 3 with a system component 5 is arranged.

The table serves, for example, as a support for vibration-isolated system components in a measurement device.

For this purpose, the table 3 can be arranged isolated against vibration on bearings (not shown), in particular on air bearings.

Maintenance apparatus 1 comprises two laterally arranged magnetic rails 7.

Each magnetic rail 7 comprises at least one beam 9 on which a respective carriage 10 can be moved horizontally.

The carriages 10 comprise solenoids (not shown) due to which the carriages 10 can be lifted from the beams 9 so that the carriages 10 are spaced apart from the beam by an air gap and can be moved on the beam 9 in contact-free manner.

Frame 2 should not be much larger than the entire system, in order to keep the space or area additionally required by the maintenance apparatus to a minimum.

The maintenance apparatus is preferably designed so that it can be completely integrated into the system without increasing the installation area required for the system.

In the present exemplary embodiment, the system component 5 is suspended on the carriages 10 via hanger means 15 and thus there is some clearance at least in the horizontal direction. There may also be some clearance in the vertical direction.

In this exemplary embodiment, the system component 5 can be lifted in the vertical direction by the hanger means 15. For this purpose, the hanger means 15 is configured as a lifting means, such as a threaded spindle, for example.

Alternatively or in combination, it is also conceivable to move the beams in the vertical direction by means of a drive 4.

Power supply for operating the solenoids that are arranged in the carriage can be achieved via the hanger means 15, for example.

The hanger means 15 are connected to the two carriages 10 which are arranged on a respective beam 9.

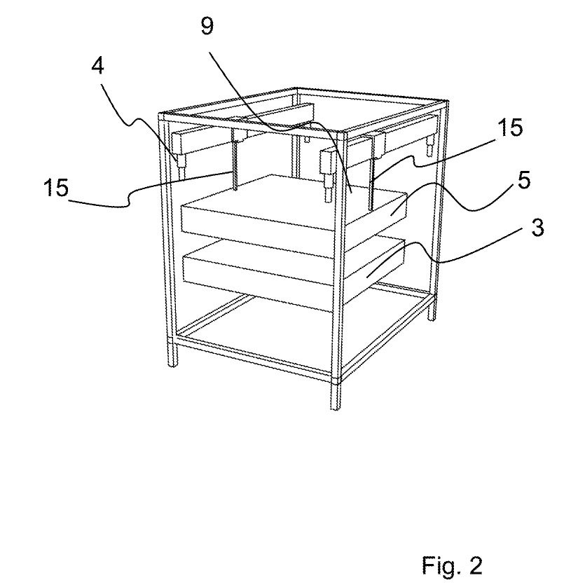

FIG. 2 now illustrates how the system component 5 has been moved vertically upwards, by hanging means 15, so as to expose the table 3.

Alternatively or in combination, the vertical displacement may as well be effected by drive 4.

In this state, the magnetic rails 7 may already be enabled.

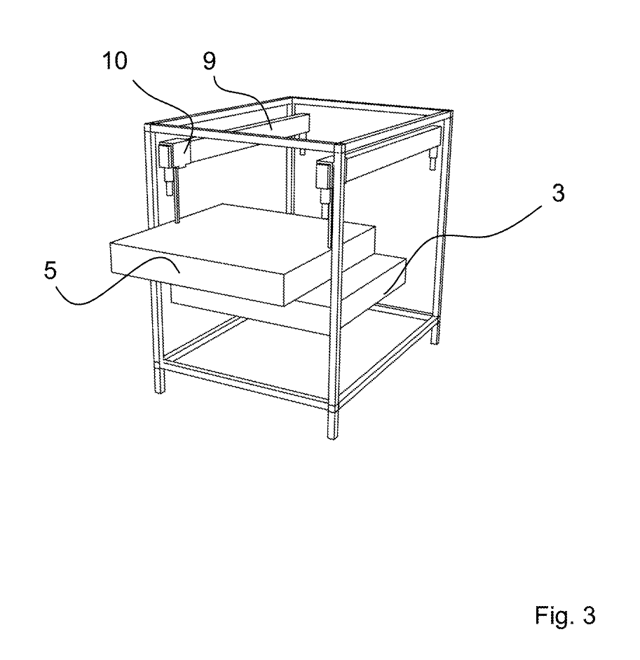

As illustrated in FIG. 3, the magnetic rails are enabled by now at the latest, so that the carriages 10 are lifted and are now freely movable on beam 9.

The system component 5 is now displaced in the horizontal direction along beam 9 into its final position.

By disabling the magnetic rail, the carriages 10 will touch down on beams 9, thus securing them against further horizontal displacement. However, the position may as well be maintained by the drive alone, without disabling the magnetic rail. Alternatively or in addition, the magnetic rail may as well be locked by other locking means such as, for example, electrically operable positive-locking features (not shown).

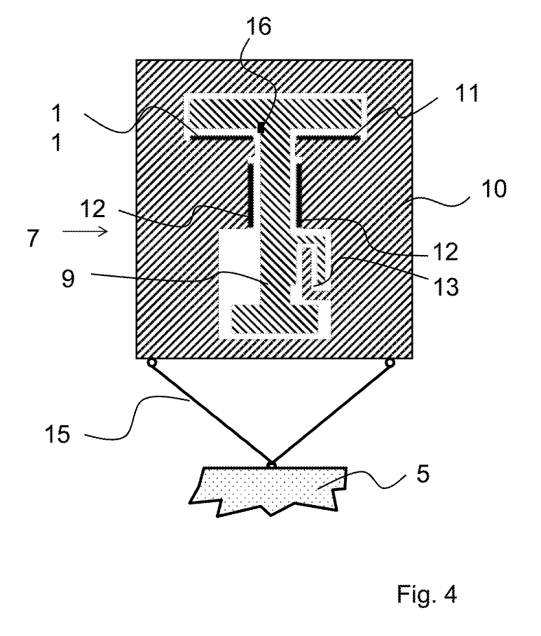

FIG. 4 shows a schematic sectional view of a magnetic rail 7.

Magnetic rail 7 comprises a carriage 10 which is of rectangular shape in this exemplary embodiment. It will be appreciated that the carriage 10 may as well have a different geometry, such as a round outer contour, for example. Carriage 10 encloses beam 9 which is in the form of a T-beam with a shorter lower strut.

The carriage comprises solenoids 11 facing the underside of beam 9, which serve to lift the carriage 10 on beam 9.

When enabling the solenoids, carriage 10 is lifted up and will then be spaced from beam 9 by a gap.

Disabling of the solenoids 11 causes the carriage 10 to touch down on beam 9 and then to be secured in the horizontal direction already by frictional engagement.

Facing the vertically extending portion of beam 9, the carriage 10 comprises laterally arranged solenoids 12 which provide lateral guidance so that the carriage 10 is spaced apart from beam 9 by air gaps also in the horizontal direction.

For controlling solenoids 11 and 12, a sensor module 16 may be used, which measures the spacing of beam 9 from carriage 10 in the horizontal and vertical directions. This also functions in contact-free manner, for example as an inductive or capacitive sensor.

Vertical guidance and horizontal lateral guidance operate independently from each other.

Furthermore, a separate linear drive 13 is provided, by which the carriage 10 can be displaced along beam 9 in the horizontal direction.

This drive also operates independently and is preferably configured as a non-contact drive. Linear drive 13 is configured so that it ensures a vertical clearance, at least over the lifting height of carriage 10. In the present exemplary embodiment, this is accomplished by angled and intertwining extensions of the carriage 10 and the beam 9.

Hanger means 15 serve to connect the system component 5 to carriage 10. For example cables or rods, in particular threaded rods, can be used as hanger means. They provide a certain clearance in the horizontal direction and in the vertical direction. Such cables or rods may be combined with a vertical drive, for example a threaded spindle, to form a lifting means.

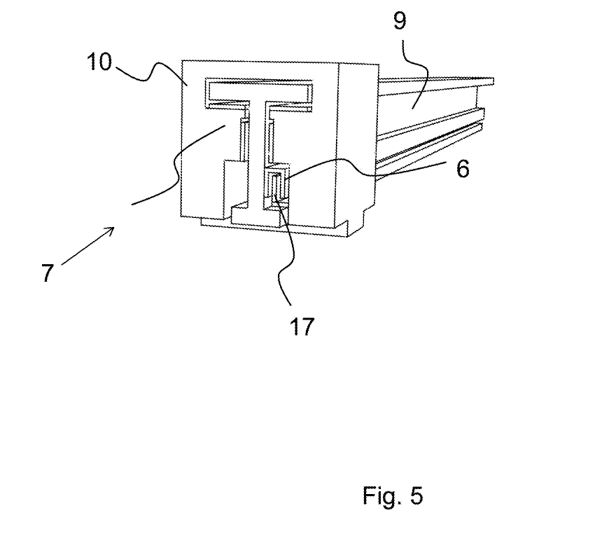

FIG. 5 shows a perspective view of a magnetic rail 7. Carriage 10 can be seen running on beam 9.

Furthermore, the intertwining rails 6, 17 of a linear drive can be seen, through which the carriage 10 is moved in the horizontal direction.

Permanent magnets that are arranged along a rail 6, 17 may serve as a stator of such a linear drive, for example.

Rail 6 is arranged on beam 9, and rail 17 on carriage 10.

Carriage 10 is essentially square in shape and has an extension on its lower surface for mounting the lifting means.

Even with a relatively short carriage 10 it is possible to achieve strong forces which are in particular sufficient to lift loads of more than 1 t.

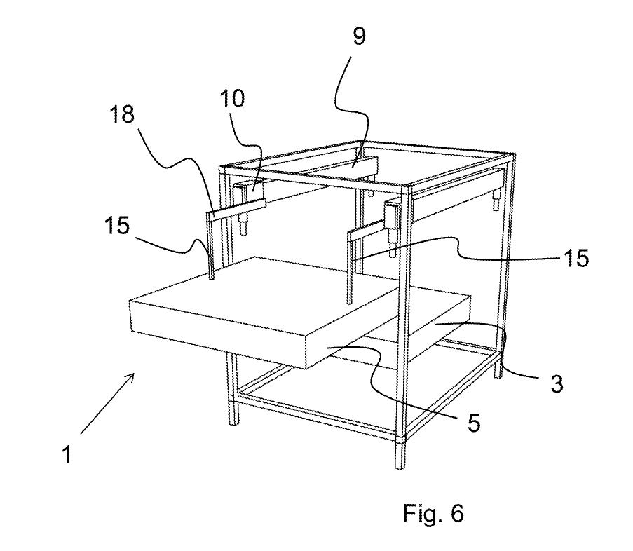

FIG. 6 shows a further embodiment of the invention, in which the system component 5 can be moved out of the system area over a greater distance than in the embodiment shown in FIGS. 1 to 3.

Otherwise, however, the maintenance apparatus 1 shown here corresponds to the previously illustrated embodiment.

In contrast to the previously illustrated embodiment, arms 18 are arranged on the carriages 10, which extend in the horizontal direction and on which the machine component 5 is suspended, preferably at its center of gravity.

As a result, the machine component 5 can be moved out of the system further. Thus, a larger area of the table 3 is exposed.

It will be apparent that the extended arms 18 exert a force on the frame of the system, which must be absorbed by the weight of the system or with a suitable attachment, so that the system does not tilt.

The invention provides a maintenance apparatus which is capable of moving even heavy loads in the horizontal and vertical directions. The maintenance apparatus according to the invention enables faster system maintenance and leads to reduced particle load of the system or the clean room.

### LIST OF REFERENCE NUMERALS

1 Maintenance apparatus
2 Frame
3 Table
4 Drive
5 System component
6 Rail
7 Magnetic rail
9 Beam
10 Carriage
11 Solenoid
12 Solenoid
13 Linear drive
15 Hanger means
16 Sensor module
17 Rail
18 Arm

1. A maintenance apparatus for use in clean rooms, the maintenance apparatus comprising at least one magnetic rail on which a system component is suspended and can be moved horizontally, and hanger means for moving the system component vertically.

2. The maintenance apparatus of claim 1, wherein the magnetic rail includes a separate non-contact linear drive for the horizontal movement.

3. The maintenance apparatus of claim 1, wherein the magnetic rail has an electromagnetically controlled lateral guide.

4. The maintenance apparatus of claim 1, wherein the magnetic rail is movable vertically by a drive.

5. The maintenance apparatus of claim 1, wherein the system component has passages for fluid, electrical or optical lines.

6. The maintenance apparatus of claim 1, wherein the at least one magnetic rail comprises a plurality of magnetic rails.

7. The maintenance apparatus of claim 1, wherein the magnetic rail comprises a beam on which at least one carriage is displaceable.

8-9. (canceled)

10. The maintenance apparatus of claim 1, wherein the maintenance apparatus is adapted for moving a mass of more than 50 kg.

11. The maintenance apparatus of claim 1, wherein the system component can be moved by more than 30% or less than 70% of its length from a center position in the horizontal direction.

12. The maintenance apparatus of claim 1, wherein the system component is part of a processing system, or part of a process control system, or part of a lithography system in the semiconductor industry.

13. The maintenance apparatus of claim 1, wherein the system component to be moved is part of a component of the system which is mounted with vibration isolation.

14. The maintenance apparatus of claim 1, wherein the system component is part of a system in the pharmaceutical or food industry.

15. The maintenance apparatus of claim 1, wherein the maintenance apparatus is part of a clean room.

16. A maintenance apparatus comprising a part of a clean room, the maintenance apparatus comprising at least one magnetic rail on which a system component, which is part of a lithography system, is suspended and can be moved horizontally, and hanger means for moving the system component vertically.

17. The maintenance apparatus of claim 16, wherein the magnetic rail includes a separate non-contact linear drive for a horizontal movement.
